(19) United States
(12) Patent Application Publication
(10) Pub. No.: US 2010/0018855 A1
(43) Pub. Date: Jan. 28, 2010

(54) INLINE CO-SPUTTER APPARATUS

(75) Inventors: Jeffrey Shane Reiter, Palo Alto, CA (US); Stephen Eric Barlow, Hayward, CA (US); Thomas Larson Greenberg, Berkeley, CA (US); Keith Kadokura, Cupertino, CA (US); Matthew James Cross, Dublin, CA (US)

Correspondence Address: Shumaker & Sieffert, P.A., 1625 Radio Drive, Suite 300, Woodbury, MN, 55125, US

(73) Assignee: Seagate Technology LLC, Scotts Valley, CA (US)

(21) Appl. No.: 12/179,131

(22) Filed: Jul. 24, 2008

(51) Int. Cl. C23C 14/34

(52) U.S. Cl. 204/192.12; 204/298.23

(57) ABSTRACT

Disclosed is an apparatus and process within a pass-by sputtering chamber, in which standard cathodes and two or more specially-sized cathodes within the sputtering chamber, mounted colinear with the direction of travel of substrates within the sputtering chamber, enabling performance of rapid adjustment of material deposited on a substrate.

### RELATED APPLICATIONS

None.

### BACKGROUND

Disclosed is an apparatus and process within a pass-by sputtering chamber, in which standard cathodes and two or more specially-sized cathodes within the sputtering chamber, mounted colinear with the direction of travel of substrates within the sputtering chamber, enabling performance of rapid adjustment of material deposited on a substrate.

### SUMMARY OF THE INVENTION

This invention is novel in the incorporation of a pair of specially sized cathodes which are mounted in the sputtering chamber. The specially sized cathodes allow adjustment of material delivered to the substrate during the sputtering process, with a very quick response time and no disruption to the vacuum integrity of the sputtering system. This also drastically reduces the manufacturing cost for target materials, allows for alloys not readily available and finite alloy tailoring for performance of the end product.

As will be realized, this invention is capable of other and different embodiments, and its details are capable of modifications in various obvious respects, all without departing from this invention. Accordingly, the drawings and description are to be regarded as illustrative in nature and not as restrictive.

### BRIEF DESCRIPTION OF THE DRAWINGS

FIG. 1 is a view of a magnetic disk drive of the related art.

FIG. 2 is a schematic representation of the film structure in accordance with a magnetic recording medium of the related art.

FIG. 3 is perspective view of a magnetic head and a magnetic disk of the related art.

FIG. 4 is a schematic view of an inline co-sputtering apparatus of the present invention.

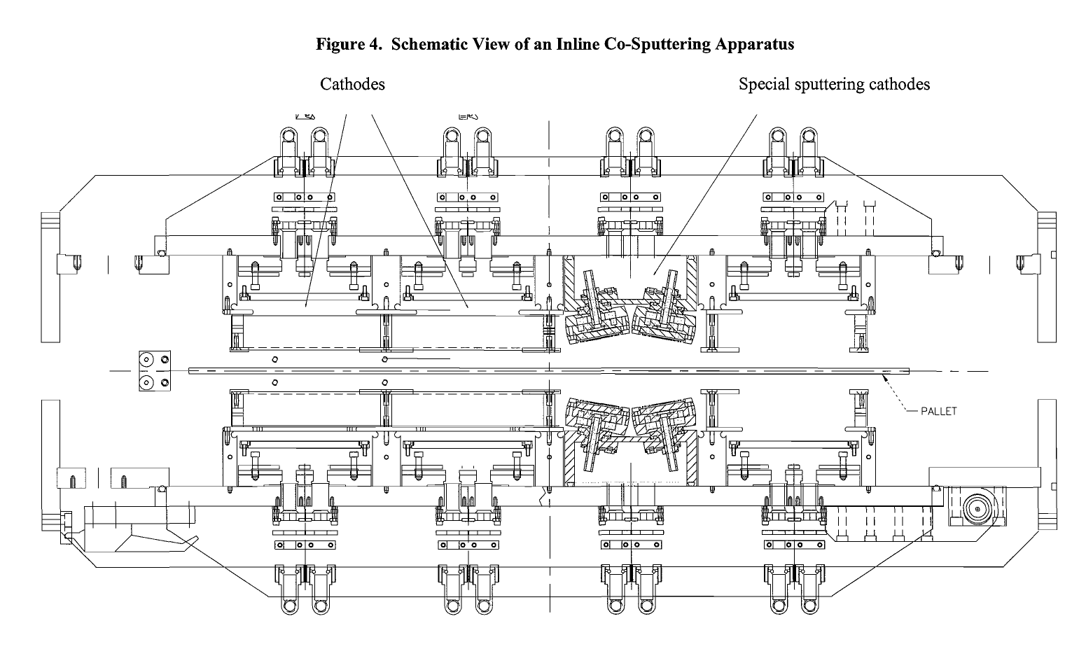

### DETAILED DESCRIPTION

This invention relates to an apparatus for making a recording media, such as thin film magnetic recording disks, and to a method of manufacturing the media. The invention has particular applicability to a highly flexible apparatus and method for manufacturing magnetic recording media having a two or more magnetic layers.

The increasing demands for higher areal recording density impose increasingly greater demands on thin film magnetic recording media in terms of remanent coercivity (Hr), magnetic remanance (Mr), coercivity squareness (S*), medium noise, i.e., signal-to-medium noise ratio (SMNR), and narrow track recording performance. It is extremely difficult to produce a magnetic recording medium satisfying such demanding requirements.

The linear recording density can be increased by increasing the Hr of the magnetic recording medium, and by decreasing the medium noise, as by maintaining very fine magnetically non-coupled grains. Medium noise in thin films is a dominant factor restricting increased recording density of high-density magnetic hard disk drives, and is attributed primarily to inhomogeneous grain size and intergranular exchange coupling. Accordingly, in order to increase linear density, medium noise must be minimized by suitable microstructure control.

According to the domain theory, a magnetic material is composed of a number of submicroscopic regions called domains. Each domain contains parallel atomic moments and is always magnetized to saturation, but the directions of magnetization of different domains are not necessarily parallel. In the absence of an applied magnetic field, adjacent domains may be oriented randomly in any number of several directions, called the directions of easy magnetization, which depend on the geometry of the crystal. The resultant effect of all these various directions of magnetization may be zero, as is the case with an unmagnetized specimen. When a magnetic filed is applied, the domains most nearly parallel to the direction of the applied field grow in size at the expense of the others. This is called boundary displacement of the domains or the domain growth. A further increase in magnetic field causes more domains to rotate and align parallel to the applied field. When the material reaches the point of saturation magnetization, no further domain growth would take place on increasing the strength of the magnetic field.

A magnetic material is said to possess a uniaxial anisotropy when all domains are oriented in the same direction in the material. On the other extreme, a magnetic material is said to be isotropic when all domains are oriented randomly.

The ease of magnetization or demagnetization of a magnetic material depends on the crystal structure, grain orientation, the state of strain, and the direction and strength of the magnetic field. The magnetization is most easily obtained along the easy axis of magnetization but most difficult along the hard axis of magnetization.

“Anisotropy energy” is the difference in energy of magnetization for these two extreme directions, namely, the easy axis of magnetization and the hard axis of magnetization. For example, a single crystal of iron, which is made up of a cubic array of iron atoms, tends to magnetize in the directions of the cube edges along which lie the easy axes of magnetization. A single crystal of iron requires about 1.4×10⁵ ergs/cm³ (at room temperature) to move magnetization into the hard axis of magnetization, which is along a cubic body diagonal.

The anisotropy energy U_{A} could be expressed in an ascending power series of the direction cosines between the magnetization and the crystal axes. For cubic crystals, the lowest-order terms take the form of Equation (1),

U_{A}=K₁(α₁²α₂²+α₂²α₃²+α₃²α₁²)+K₂(α₁²α₂²α₃²) (1)

where α₁, α₂ and α₃ are direction cosines with respect to the cube, and K₁ and K₂ are temperature-dependent parameters characteristic of the material, called anisotropy constants.

Anisotropy constants can be determined from (1) analysis of magnetization curves, (2) the torque on single crystals in a large applied field, and (3) single crystal magnetic resonance.

The total energy of a magnetic substance depends upon the state of strain in the magnetic material and the direction of magnetization through three contributions. The first two consist of the crystalline anisotropy energy of the unstrained lattice plus a correction that takes into account the dependence of the anisotropy energy on the state of strain. The third contribution is that of the elastic energy, which is independent of magnetization direction and is a minimum in the unstrained state. The state of strain of the crystal will be that which makes the sum of the three contributions of the energy a minimum. The result is that, when magnetized, the lattice is always distorted from the unstrained state, unless there is no anisotropy.

“Magnetostriction” refers to the changes in dimension of a magnetic material when it is placed in magnetic field. It is caused by the rotation of domains of a magnetic material under the action of magnetic field. The rotation of domains gives rise to internal strains in the material, causing its contraction or expansion.

The requirements for high areal density impose increasingly greater requirements on magnetic recording media in terms of coercivity, remanent squareness, low medium noise and narrow track recording performance. It is extremely difficult to produce a magnetic recording medium satisfying such demanding requirements, particularly a high-density magnetic rigid disk medium for longitudinal and perpendicular recording. The magnetic anisotropy of longitudinal and perpendicular recording media makes the easily magnetized direction of the media located in the film plane and perpendicular to the film plane, respectively. The remanent magnetic moment of the magnetic media after magnetic recording or writing of longitudinal and perpendicular media is located in the film plane and perpendicular to the film plane, respectively.

Almost all the manufacturing of a disk media takes place in clean rooms where the amount of dust in the atmosphere is kept very low, and is strictly controlled and monitored. After one or more cleaning processes on a non-magnetic substrate, the substrate has an ultra-clean surface and is ready for the deposition of layers of magnetic media on the substrate. The apparatus for depositing all the layers needed for such media could be a static sputter system or a pass-by system, where all the layers except the lubricant are deposited sequentially inside a suitable vacuum environment.

A substrate material conventionally employed in producing magnetic recording rigid disks comprises an aluminum-magnesium (Al—Mg) alloy. Such Al—Mg alloys are typically electrolessly plated with a layer of NiP at a thickness of about 15 microns to increase the hardness of the substrates, thereby providing a suitable surface for polishing to provide the requisite surface roughness or texture.

Other substrate materials have been employed, such as glass, e.g., an amorphous glass, glass-ceramic material which comprises a mixture of amorphous and crystalline materials, and ceramic materials. Glass-ceramic materials do not normally exhibit a crystalline surface. Glasses and glass-ceramics generally exhibit high resistance to shocks.

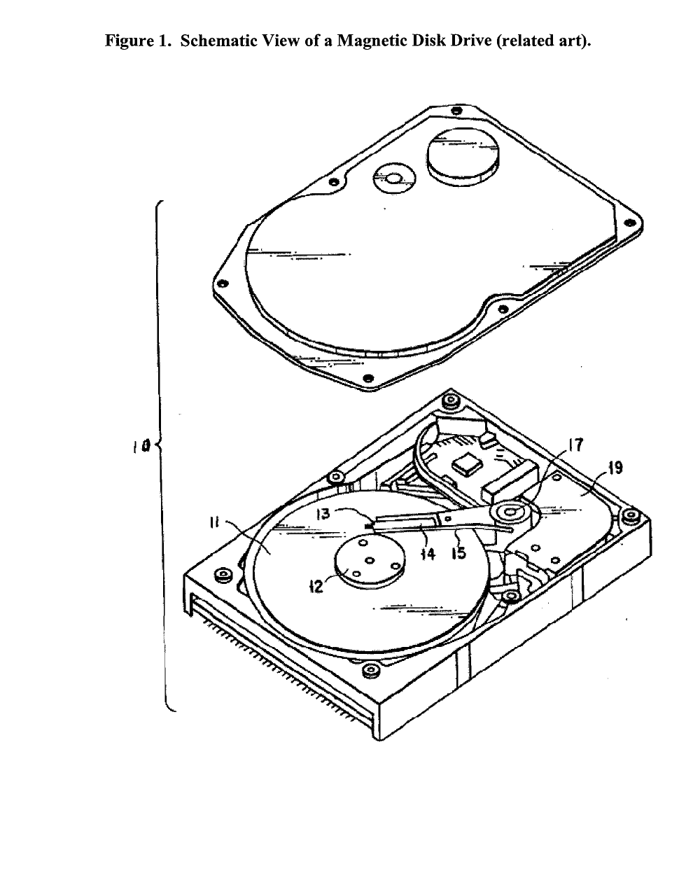

FIG. 1 shows the schematic arrangement of a magnetic disk drive 10 using a rotary actuator. A disk or medium 11 is mounted on a spindle 12 and rotated at a predetermined speed. The rotary actuator comprises an arm 15 to which is coupled a suspension 14. A magnetic head 13 is mounted at the distal end of the suspension 14. The magnetic head 13 is brought into contact with the recording/reproduction surface of the disk 11. The rotary actuator could have several suspensions and multiple magnetic heads to allow for simultaneous recording and reproduction on and from both surfaces of each medium.

An electromagnetic converting portion (not shown) for recording/reproducing information is mounted on the magnetic head 13. The arm 15 has a bobbin portion for holding a driving coil (not shown). A voice coil motor 19 as a kind of linear motor is provided to the other end of the arm 15. The voice motor 19 has the driving coil wound on the bobbin portion of the arm 15 and a magnetic circuit (not shown). The magnetic circuit comprises a permanent magnet and a counter yoke. The magnetic circuit opposes the driving coil to sandwich it. The arm 15 is swingably supported by ball bearings (not shown) provided at the upper and lower portions of a pivot portion 17. The ball bearings provided around the pivot portion 17 are held by a carriage portion (not shown).

A magnetic head support mechanism is controlled by a positioning servo driving system. The positioning servo driving system comprises a feedback control circuit having a head position detection sensor (not shown), a power supply (not shown), and a controller (not shown). When a signal is supplied from the controller to the respective power supplies based on the detection result of the position of the magnetic head 13, the driving coil of the voice coil motor 19 and the piezoelectric element (not shown) of the head portion are driven.

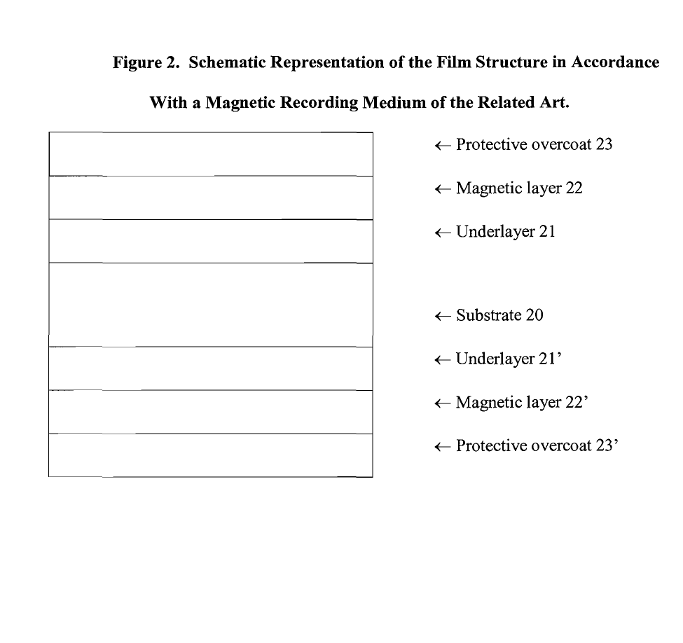

A cross sectional view of a conventional longitudinal recording disk medium is depicted in FIG. 2. A longitudinal recording medium typically comprises a non-magnetic substrate 20 having sequentially deposited on each side thereof an underlayer 21, 21′, such as chromium (Cr) or Cr-alloy, a magnetic layer 22, 22′, typically comprising a cobalt (Co)-base alloy, and a protective overcoat 23, 23′, typically containing carbon. Conventional practices also comprise bonding a lubricant topcoat (not shown) to the protective overcoat. Underlayer 21, 21′, magnetic layer 22, 22′, and protective overcoat 23, 23′, are typically deposited by sputtering techniques. The Co-base alloy magnetic layer deposited by conventional techniques normally comprises polycrystallites epitaxially grown on the polycrystal Cr or Cr-alloy underlayer.

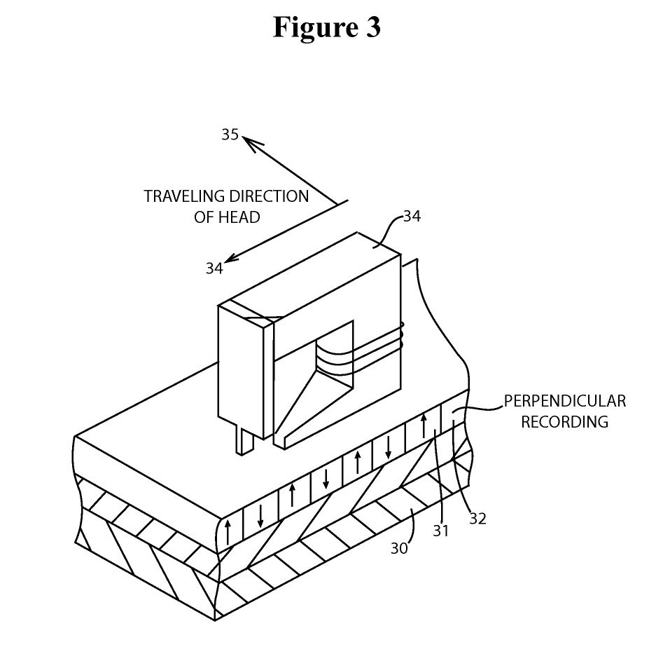

A conventional perpendicular recording disk medium, shown in FIG. 3, is similar to the longitudinal recording medium depicted in FIG. 2, but with the following differences. First, a conventional perpendicular recording disk medium has soft magnetic underlayer 31 of an alloy such as Permalloy instead of a Cr-containing underlayer. Second, as shown in FIG. 3, magnetic layer 32 of the perpendicular recording disk medium comprises domains oriented in a direction perpendicular to the plane of the substrate 30. Also, shown in FIG. 3 are the following: (a) read-write head 33 located on the recording medium, (b) traveling direction 34 of head 33 and (c) transverse direction 35 with respect to the traveling direction 34.

The underlayer and magnetic layer are conventionally sequentially sputter deposited on the substrate in an inert gas atmosphere, such as an atmosphere of pure argon. A conventional carbon overcoat is typically deposited in argon with nitrogen, hydrogen or ethylene. Conventional lubricant topcoats are typically about 20 Å thick.

A soft underlayer should preferably be made of soft magnetic materials and the recording layer should preferably be made of hard magnetic materials. The terms “recording layer” and “magnetic layer” are equivalent and denote the same layer. A soft underlayer is relatively thick compared to other layers. Any layers between the soft underlayer and the recording layer is called interlayer or intermediate layer. An interlayer can be made of more than one layer of non-magnetic materials. The purpose of the interlayer is to prevent an interaction between the soft magnetic underlayer and recording layer. An interlayer could also promote the desired properties of the recording layer. Conventional (longitudinal) media do not have a soft magnetic underlayer. Therefore, the layers named as “underlayer,” “seed layer,” “sub-seed layer,” or “buffer layer” of longitudinal media are somewhat equivalent to the intermediate layer(s) of perpendicular media.

It is recognized that the magnetic properties, such as Hr, Mr, S* and SMNR, which are critical to the performance of a magnetic alloy film, depend primarily upon the microstructure of the magnetic layer which, in turn, is influenced by one or more underlying layers on which it is deposited. It is also recognized that an underlayer made of soft magnetic films is useful in perpendicular recording media because a relatively thick (compared to magnetic layer) soft underlayer provides a return path for the read-write head and amplifies perpendicular component of the write field in the recording layer. However, Barkhausen noise caused by domain wall motions in the soft underlayer can be a significant noise source. Since the orientation of the domains can be controlled by the uniaxial anisotropy, introducing a uniaxial anisotropy in the soft underlayer would be one way to suppress Barkhausen noise. When the uniaxial anisotropy is sufficiently large, the domains would preferably orient themselves along the anisotropy axis.

The uniaxial anisotropy could be controlled in several ways in the soft magnetic thin film materials. The most frequently applied methods are post-deposition annealing while applying a magnetic field and applying a bias magnetic field during deposition. However, both methods can cause complications in the disk manufacturing process.

A “soft magnetic” material is material that is easily magnetized and demagnetized. As compared to a soft magnetic material, a “hard magnetic” material is one that neither magnetizes nor demagnetizes easily. The problem of making soft magnetic materials conventionally is that they usually have many crystalline boundaries and crystal grains oriented in many directions. In such metals, the magnetization process is accompanied by much irreversible Block wall motion and by much rotation against anisotropy, which is usually irreversible. See Mc-Graw Hill Encyclopedia of Science & Technology, Vol. 5, 366 (1982). Mc-Graw Hill Encyclopedia of Science & Technology further states that the preferred soft material would be a material fabricated by some inexpensive technique that results in all crystal grains being oriented in the same or nearly the same direction. Id. Applicants, however, have found that “all grains” oriented in the same direction would be very difficult to produce and would not be the “preferred soft material.” In fact, applicants have found that very high anisotropy is not desirable.

Two types of sputtering chamber design are known in the related art. The first type of design is an older technology known as a static chamber in which substrate media does not move while sputtering takes place. The second type of design is a newer technology known as a pass-by chamber, in which the substrate media travel within the sputtering chamber as sputtering takes place.

In the field of in-line, dynamic pass-by disk coating machines, some prior systems have attempted to coat the substrates with fixed alloys from sputtering targets, but if the composition of the alloy was not quite correct, there was no option but to replace the target material with a different target by venting the vacuum system and installing it. The time to vent, refurbish and re-qualify the system is too long for high throughput operations. To promote better manufacturing capability for current and future products, a more responsive system for the adjustment of the alloy makeup in situ was needed.

This invention provides an apparatus and method for adjusting material delivered to a substrate during the sputtering process, with a very quick response time and no disruption to the vacuum integrity of the sputtering system. The present invention utilizes a pass-by sputtering chamber design containing standard cathodes, with the added novelty that the chamber further incorporates a pair of specially sized cathodes which are located in the sputtering chamber and are placed substantially colinear with the direction of travel of the substrates.

The nominal size for standard cathodes is 5 inches. The specially-sized cathodes are nominally 2 inches, which is sized to allow a pair of specially-sized cathodes to be mounted into a cavity designed to accommodate one standard size cathode. The specially-sized cathodes may be other sizes as long as they both fit within the cavity of one standard cathode inside the sputtering chamber. It is important that both sputtering cathodes be mounted in the same cavity. If the sputtering cathodes are not in the same cathode cavity, they will produce two distinct layers rather than one alloy layer comprising a combination of the material from the two specially-sized cathodes. The specially-sized cathodes may be mounted so that they individually point at a range of angles with respect to each other and with respect to the chamber, and with respect to the direction of travel of the substrates. The pointing of a cathode may be indicated by the direction of an axis of the cathode, where the axis may be indicated by, for example, an axis of symmetry of the cathode, or a geometric normal to the face of the cathode, or the direction which material is ejected from the cathode. The specially-sized cathodes also may be mounted at a range of heights above the substrates, where height is measured from the closest approach of the substrate to the cathode. As the pointing angle and the height of one or more cathodes is varied, the properties of the substrates will be affected. The affected substrate properties include the alloy ratio and the surface energy.

The cathodes build up layers of materials on the disks in the order in which the disks pass by the cathodes. The specially-sized cathodes may be placed before, after, or between the standard sized cathodes, depending on which layer is intended to be the co-sputter layer. The composition of the layer deposited by the cathodes during sputtering may be adjusted and varied dynamically from one to another substrate passing through the sputtering chamber by varying the power ratio between the two specially-sized cathodes. The basis for making adjustments may include feedback from the monitoring of the production line, or desire to change the alloy composition, or production needs. This results in great flexibility in the ratio of alloys in the resulting composition on the substrate.

In this case, what is deposited on the substrate depends on the power ratio between the two specially-sized co-sputtering cathodes.

The power of a cathode is the product of voltage times current. Either the voltage or the current may be varied to adjust the cathode power. This technique will be familiar to a person of ordinary skill in the art. However, by having the two specially-sized cathodes within the sputtering chamber together with the standard cathodes, the composition can be adjusted during sputtering without breaking the vacuum of the chamber. This allows for a response time which is quick with respect to the time it would take to shut down the sputtering chamber, change the target material, and re-establish a vacuum.

The present invention has the additional benefit of allowing for alloys not readily available, or fine tailoring of the alloys, through variation of the power ratios of the cathodes.

In a second embodiment of the apparatus, the specially-sized cathodes are preferably attached to one or more special mounting structures, and the mounting structures are in turn attached to the chamber so that the specially-sized cathodes are secured within the cavity of a standard cathode. The mounting structure allows for adjusting the ‘source-to-substrate’ distance, as well as adjusting the angle of deposition, in order to achieve desired properties of the substrates.

The above description is presented to enable a person skilled in the art to make and use the invention, and is provided in the context of a particular application and its requirements. Various modifications to the preferred embodiments will be readily apparent to those skilled in the art, and the generic principles defined herein may be applied to other embodiments and applications without departing from the spirit and scope of the invention. Thus, this invention is not intended to be limited to the embodiments shown, but is to be accorded the widest scope consistent with the principles and features disclosed herein.

This application may disclose several numerical range limitations. Persons skilled in the art would recognize that the numerical ranges disclosed inherently support any range within the disclosed numerical ranges even though a precise range limitation is not stated verbatim in the specification because this invention can be practiced throughout the disclosed numerical ranges. A holding to the contrary would “let form triumph over substance” and allow the written description requirement to eviscerate claims that might be narrowed during prosecution simply because the applicants broadly disclose in this application but then might narrow their claims during prosecution. Where the term “plurality” is used, that term shall be construed to include the quantity of one, unless otherwise stated. The entire disclosure of the patents and publications referred in this application are hereby incorporated herein by reference. Finally, the implementations described above and other implementations are within the scope of the following claims.

1. An apparatus for performing rapid adjustment of material deposited on a substrate within a pass-by sputtering chamber, comprising:
a plurality of standard cathodes; and
two or more specially-sized cathodes, each specially-sized cathode having an axis and a face;
wherein the specially-sized cathodes are located within one or more cavities within the sputtering chamber; and
wherein the specially-sized cathodes and the standard cathodes are mounted substantially colinear with the direction of travel of substrates within the sputtering chamber.

2. The apparatus of claim 1, wherein the specially-sized cathodes are attached to a mounting fixture, and the mounting fixture is attached to the cavity within the sputtering chamber.

3. The apparatus of claim 1, wherein the angle between the axis of at least one specially-sized cathode and the direction of travel of the substrates is adjustable.

4. The apparatus of claim 1, wherein the closest separation between at least one specially-sized cathode and the substrates is adjustable.

5. The apparatus of claim 1, wherein the cathode axis is determined as an axis of symmetry of the cathode.

6. The apparatus of claim 1, wherein the cathode axis is determined as a geometric normal to the face of the cathode.

7. The apparatus of claim 1, wherein the cathode axis is determined as the direction which material is ejected from the cathode.

8. A method of adjustably sputtering material onto a substrate, comprising the steps of:
supplying the apparatus of claim 1;
adjusting the power ratio between at least a portion of the specially-sized cathodes to produce a desired material composition on the substrates.

9. The method of claim 8, wherein the power ratio is adjusted by changing the voltage supplied to at least one specially-sized cathode.

10. The method of claim 8, wherein the power ratio is adjusted by changing the current supplied to at least one specially-sized cathode.

11. The method of claim 8, comprising the additional step of adjusting the angle of a specially-sized cathode with respect to the direction of travel of the substrates.

12. The method of claim 8, comprising the additional step of adjusting the separation of a specially-sized cathode from the closest approach of the substrates.

13. The method of claim 8, comprising the additional step of monitoring feedback from the production line, and using the feedback to determine the desired amount of adjustment.
